(19) United States
(12) Patent Application Publication
(10) Pub. No.: US 2015/0002785 A1
(43) Pub. Date: Jan. 1, 2015

(54) BACKLIGHT MODULE AND LIQUID CRYSTAL DISPLAY

(71) Applicants: Chong Huang, Shenzhen (CN); Jiahe Cheng, Shenzhen (CN)

(72) Inventors: Chong Huang, Shenzhen (CN); Jiahe Cheng, Shenzhen (CN)

(73) Assignee: Shenzhen China Star Optoelectronics Technology Co., Ltd., Shenzhen (CN)

(21) Appl. No.: 13/502,743

(22) PCT Filed: Mar. 26, 2012
(86) PCT No.: PCT/CN2012/073057

§ 371 Date: Apr. 19, 2012

(30) Foreign Application Priority Data
Mar. 13, 2012 (CN) 201210065197.8

(51) Int. Cl. G02F 1/1335; F21V 8/00; H05K 9/00

(52) U.S. Cl. CPC G02F 1/133615; H05K 9/0054; H05K 9/0045; G02B 6/0066
USPC 349/65; 362/633

(57) ABSTRACT

A backlight module and a liquid crystal display are disclosed, and the backlight module comprises a plastic front frame, a rubber frame, a chipset and an electromagnetic shield member where the electromagnetic shield member is disposed around the chipset, for the shield of outside electromagnetic interference (EMI) to the chipset. Once the front frame is made of plastic material, the electromagnetic shield member can be used to shield the outside EMI to the chipset, which assures the stability of the control signals of the chipset and further assures the quality of the screen display.

### BACKGROUND OF THE INVENTION

1. Field of the Invention

The present invention relates to liquid crystal display technical domain. More particularly, the present invention relates to a backlight module and a liquid crystal display.

2. Description of the Prior Art

With the advancement of liquid crystal techniques, the demand for the parts of the liquid crystal display is getting higher.

To exemplify a backlight module, referring to FIG. 1, FIG. 1 is a schematic diagram of the structure of the backlight module of prior techniques.

The backlight module comprises a front frame 11, a liquid crystal panel 12, a backboard 13, a chipset 14 (for instance: chip or thin film flip chip), a light source 15, an optical module 16 (for instance: light guide plate, optical membrane) and a rubber frame 17, etc.

The backboard 13 supports the optical module 16 and the rubber frame 17, and the rubber frame 17 bears the liquid crystal panel 12 and supports the front frame 11. The light source 15 is disposed on an inner side of a side wall of the backboard 13. The chipset 14 inputs control signals for the control of plural liquid crystal cells of the liquid crystal panel 12 to unceasingly alter their twisted angles promptly. Meanwhile, the emitted light rays from the light source 15 are scattered by the optical module 16 and enter the liquid crystal panel 12, to realize backlight provision by the backlight module and color conversion of the liquid crystal panel 12.

Wherein, the front frame 11 is formed by metal substances or plastic substances. In the prior techniques, for cost saving sake, the front frame 11 is mostly made of a plastic substance. As the plastic substance is applied to form the front frame 11, it fails to shield the electromagnetic interference (EMI) from the nearby existed electromagnetic radiation. The chipset 14 then suffers easily from the EMI, leading to abnormality of control signals that further affects the screen display quality of the liquid crystal display.

Therefore, there is quite essential to settle the aforementioned technical issues.

### SUMMARY OF THE INVENTION

An objective of the present invention is to provide a backlight module, to settle a prior technical issue of the front frame made of plastic substances that fails to shield effectively the chipset, which results in the chipset suffered easily by the nearby electromagnetic interference (EMI), and further leads to a technical issue of abnormality of control signals.

To settle the aforementioned issue, the present invention constructs a backlight module, comprising a plastic front frame, a rubber frame, a backboard and a chipset where the chipset is disposed in between the plastic front frame and the rubber frame, wherein:

the backlight module further comprises an electromagnetic shield member that is disposed in between the plastic front frame and the chipset, and the electromagnetic shield member is electrically connected to the backboard, to form an electromagnetic shield surrounding;

the electromagnetic shield member is used to isolate the external EMI to the chipset.

In the backlight module of this invention, the electromagnetic shield member is disposed on the plastic front frame.

In the backlight module of this invention, the electromagnetic shield member is fitted or inlaid fixedly to an inner side of the plastic front frame.

In the backlight module of this invention, the electromagnetic shield member is a metal cap or a metal mesh.

In the backlight module of this invention, the electromagnetic shield member is one-piece shaped in the interior of the plastic front frame.

The other objective of the present invention is to provide a backlight module, to settle a prior technical issue of a plastic front frame that fails to shield effectively the chipset, which results in the chipset suffered easily by the nearby EMI, and further leads to a technical issue of abnormality of control signals.

To settle the aforementioned issue, the present invention constructs a backlight module, comprising a plastic front frame, a rubber frame and a chipset where the chipset is disposed in between the plastic front frame and the rubber frame;

the backlight module further comprises an electromagnetic shield member that is disposed around the chipset, for the shield of outside EMI to the chipset.

In the backlight module of this invention, the electromagnetic shield member is disposed in between the plastic front frame and the chipset, and is disposed on the plastic front frame.

In the backlight module of this invention, the electromagnetic shield member is fitted or inlaid fixedly to the plastic front frame.

In the backlight module of this invention, the electromagnetic shield member is a metal cap or a metal mesh.

In the backlight module of this invention, the electromagnetic shield member is one-piece shaped in the interior of the plastic front frame.

In the backlight module of this invention, the backlight module further comprises a backboard, and the electromagnetic shield member is electrically connected to the backboard, to form an electromagnetic shield surrounding.

Another objective of the present invention is to provide a liquid crystal display, to settle a prior technical issue of a front frame made of a plastic substance that fails to shield effectively the chipset, which results in the chipset suffered easily by the nearby EMI, and further leads to a technical issue of abnormality of control signals.

To settle the aforementioned issue, the present invention constructs a liquid crystal display, the liquid crystal display comprises a backlight module, and the backlight module comprises a plastic front frame, a rubber frame and a chipset where the chipset is disposed in between the plastic front frame and the rubber frame, and the backlight module further comprises an electromagnetic shield member that is disposed close to the chipset, for the shield of outside EMI to the chipset.

In the liquid crystal display of this invention, the electromagnetic shield member is disposed in between the plastic front frame and the chipset, and is disposed on the plastic front frame.

In the liquid crystal display of this invention, the electromagnetic shield member is fitted or inlaid fixedly to the plastic front frame.

In the liquid crystal display of this invention, the electromagnetic shield member is a metal cap or a metal mesh.

In the liquid crystal display of this invention, the electromagnetic shield member is one-piece shaped in the interior of the plastic front frame.

Relative to the prior techniques, the electromagnetic shield member of this invention is disposed around the chipset. Once the front frame is made of plastic substances, it can count on the electromagnetic shield member for the shield of the chipset against outside electromagnetic interference, which assures the stability of the control signals of the chipset, and further assures the quality of the screen display.

This invention is detailed described with reference to the following preferred embodiments and the accompanying drawings for better comprehension.

### BRIEF DESCRIPTION OF THE DRAWINGS

FIG. 1 is a schematic diagram of the structure of a backlight module of prior techniques;

FIG. 2 is a schematic diagram of the structure of the backlight module of the first preferred embodiment of the present invention; and

FIG. 3 is a schematic diagram of the structure of the backlight module of the second preferred embodiment of the present invention.

### DETAILED DESCRIPTION OF THE INVENTION

The following embodiments are described with reference to the following accompanying drawings which exemplify the realizations of this invention.

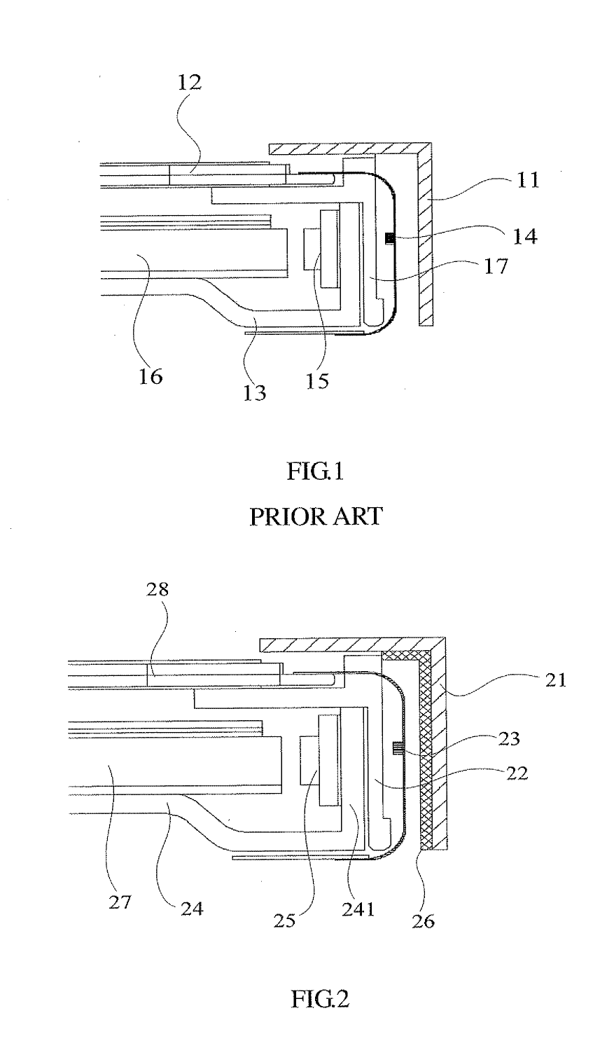

Referring to FIG. 2, FIG. 2 is a schematic diagram of the structure of the backlight module of the first preferred embodiment of the present invention.

The backlight module comprises a plastic front frame 21, a rubber frame 22, a chipset 23, a backboard 24, a light source 25, an electromagnetic shield member 26, an optical module 27 and a liquid crystal panel 28 where the backboard 24 comprises a vertically disposed sidewall 241.

Wherein, the rubber frame 22 is disposed at an outer side of the sidewall 241 and is born by the sidewall 241, and the rubber frame 22 bears the liquid crystal panel 28.

The light source 25 is disposed at the inner side of the sidewall 241, and corresponds to the optical module 27 where the light source 25 is a side light source thereto. For instance, the light source 25 is a light bar with plural light emitting diodes (LEDs). The chipset 23 is disposed at the outer side of the rubber frame 22, and joins the light source 25 through the rubber frame 22 and the sidewall 241. The rubber frame 22 further supports the plastic front frame 21 while the chipset 23 is disposed in between the plastic front frame 21 and the rubber frame 22.

Wherein, the electromagnetic shield member 26 is close to the chipset 23 and is disposed in between the plastic front frame 21 and the chipset 23, for the shield and isolation of outside electromagnetic interference (EMI) to the chipset 23.

In the first preferred embodiment shown in FIG. 2, the electromagnetic shield member 26 is disposed at the inner side of the plastic front frame 21. The electromagnetic shield member 26 is preferably fitted or inlaid fixedly to the inner side of the plastic front frame 21. It surely can be any other way for the electromagnetic shield member 26 to be disposed on the plastic front frame 21, for instance, adopting the Insert Molding approach for shaping with the plastic front frame 21 into one piece. And there is no enumeration in detail hereto.

Wherein, the electromagnetic shield member 26 is further electrically connected to the backboard 24 (not shown in the figure), to form an electromagnetic shield surrounding to the chipset 23, for providing better shield of outside EMI.

In the embodiment implementation, the electromagnetic shield member 26 can further extend to join fixedly an outer side (not shown) of the sidewall 241 of the rubber frame 22, such that the electromagnetic shield member 26 encircles the chipset 23 to shield against outside and inside EMI. And there is no enumeration in detail hereto.

In the first preferred embodiment shown in FIG. 2, the electromagnetic shield member 26 is a metal mesh. The electromagnetic shield member 26 surely can be a metal cap, and can be made of other metal substances or other structures as long as it can shield against nearby EMI. And there is no enumeration in detail hereto. The aforementioned metal substances comprise copper, iron, nickel, gold, silver or other metals and alloys.

Wherein, the chipset 23 is preferably a chip on film (COF) structure, which is to attach fixedly current source driver chip of the backlight module on the flexible circuit board (FCB) where one end of the chipset 23 is electrically connected to the liquid crystal panel 28 while the other end to a printed circuit board (PCB) of the liquid crystal display.

The working principle of the first preferred embodiment of the backlight module shown in FIG. 2 is as follows:

During the working of the liquid crystal display, the chipset 23 is set to input control signals for the control of plural liquid crystal cells of the liquid crystal panel 28 to unceasingly alter their twisted angles promptly, and the light source 25 radiates at the same time. The emitted light rays from the light source 25 are scattered uniformly by the optical module 27 and enter the liquid crystal panel 28, and cope with the changing of the twisted angle of the liquid crystal molecules of the liquid crystal cells to decide the final color of output rays, which then realizes backlight provision by the backlight module and color conversion of the liquid crystal panel 28.

Once outside EMI exists, for instance, a cell phone user in use at the nearby of a liquid crystal display, the electromagnetic shield member 26 can effectively block the outside electromagnetic radiation to shield the chipset 23 against nearby EMI which assures the stability of the control signals of the chipset and further assures the quality of the screen display, provided that the electromagnetic shield member 26 nears the chipset 23 and is disposed in between the plastic front frame 21 and the chipset 23 while the electromagnetic shield member 26 is a metal mesh.

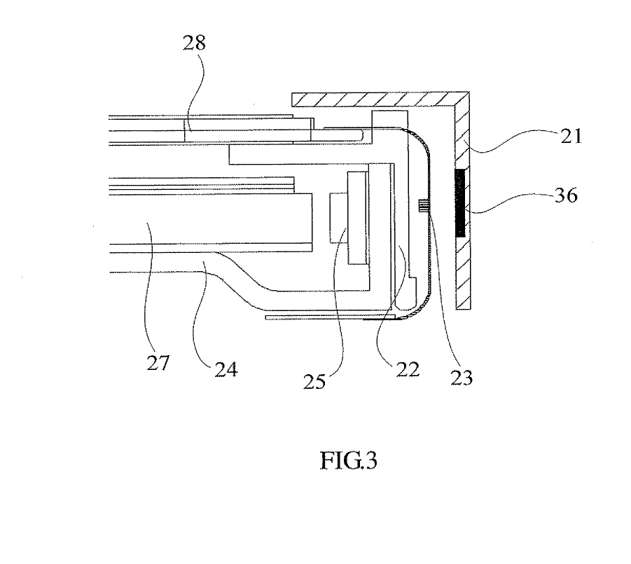

FIG. 3 is a schematic diagram of the structure of the backlight module of the second preferred embodiment of the present invention.

The backlight module of this invention comprises a plastic front frame 21, a rubber frame 22, a chipset 23, a backboard 24, a light source 25, an electromagnetic shield member 36, an optical module 27 and a liquid crystal panel 28.

Compared with the first preferred embodiment shown in FIG. 2, the second preferred embodiment shown in FIG. 3 is characterized by its one-piece forming of the electromagnetic shield member 36 in the interior of the plastic front frame 21.

In the embodiment implementation, by means of simultaneous dual plastics injections into the plastic front frame 21, which comprise a first material made up of plastic compound and conductive particles and a second material made of plastic compound only where the dual plastic injections are forming the electromagnetic shield member 36 and the body of the plastic front frame 21 at the same time. The locations for the plastic injections correspond to the chipset 23, to form the electromagnetic shield member 36 capable of shielding the outside electromagnetic radiation, for the shield of outside EMI to the chipset 23.

The working principle of the second preferred embodiment of the backlight module shown in FIG. 3 is as follows:

During the working of the liquid crystal display, the chipset 23 is set to input control signals for the control of plural liquid crystal cells of the liquid crystal panel 28 to unceasingly alter their twisted angles promptly, and the light source 25 radiates at the same time. The emitted light rays from the light source 25 are scattered uniformly by the optical module 27 and enter the liquid crystal panel 28, and cope with the changing of the twisted angle of the liquid crystal molecules of the liquid crystal cells to decide the final color of output rays, which then realizes backlight provision by the backlight module and color conversion of the liquid crystal panel 28.

Once outside EMI exists, for instance, a cell phone user in use at the nearby of a liquid crystal display, the electromagnetic shield member 36 can effectively block the outside electromagnetic radiation to shield the chipset 23 against nearby EMI which assures the stability of the control signals of the chipset 23 and further assures the quality of the screen display, provided that the electromagnetic shield member 26 forms in the plastic front frame 21 and is made of material containing plastic substances and corresponds to the chipset 23.

Relative to the prior techniques, this invention features an electromagnetic shield member around the chipset. Once the front frame is made of plastic material, the electromagnetic shield member can be used to shield the outside EMI to the chipset, which assures the stability of the control signals of the chipset 23 and further assures the quality of the screen display.

In general, although a few preferred embodiments of the present invention have been disclosed, the above preferred embodiments are not used for limiting this invention, and it will be understood by those of ordinary skill in the art that various changes in form and details may be made therein without departing from the spirit and scope of the present invention.

What is claimed is:

1. A backlight module, comprising a plastic front frame, a rubber frame, a backboard and a chipset where the chipset is disposed in between the plastic front frame and the rubber frame, wherein:
the backlight module further comprises an electromagnetic shield member where the electromagnetic shield member is disposed in between the plastic front frame and the chipset, and the electromagnetic shield member is electrically connected to the backboard, to form an electromagnetic shield surrounding to the chipset;
the electromagnetic shield member is used to isolate the external electromagnetic interference (EMI) to the chipset.

2. The backlight module as claimed in claim 1, wherein the electromagnetic shield member is disposed on the plastic front frame.

3. The backlight module as claimed in claim 2, wherein the electromagnetic shield member is fitted or inlaid fixedly to an inner side of the plastic front frame.

4. The backlight module as claimed in claim 3, wherein the electromagnetic shield member is a metal cap or a metal mesh.

5. The backlight module as claimed in claim 1, wherein the electromagnetic shield member is one-piece shaped in the interior of the plastic front frame.

6. A backlight module, comprising a plastic front frame, a rubber frame and a chipset where the chipset is disposed in between the plastic front frame and the rubber frame; wherein:
the backlight module further comprises an electromagnetic shield member where the electromagnetic shield member is disposed around the chipset, for the shield of outside EMI to the chipset.

7. The backlight module as claimed in claim 6, wherein the electromagnetic shield member is disposed in between the plastic front frame and the chipset, and is disposed on the plastic front frame.

8. The backlight module as claimed in claim 7, wherein the electromagnetic shield member is fitted or inlaid fixedly to an inner side of the plastic front frame.

9. The backlight module as claimed in claim 8, wherein the electromagnetic shield member is a metal cap or a metal mesh.

10. The backlight module as claimed in claim 6, wherein the electromagnetic shield member is one-piece shaped in the interior of the plastic front frame.

11. The backlight module as claimed in claim 6, wherein the backlight module further comprises a backboard, and the electromagnetic shield member is electrically connected to the backboard, to form an electromagnetic shield surrounding.

12. A liquid crystal display, the liquid crystal display comprising a backlight module, and the backlight module comprising a plastic front frame, a rubber frame and a chipset where the chipset is disposed in between the plastic front frame and the rubber frame, and the backlight module further comprises an electromagnetic shield member that is disposed close to the chipset, for the shield of outside EMI to the chipset.

13. The liquid crystal display as claimed in claim 12, wherein the electromagnetic shield member is disposed in between the plastic front frame and the chipset, and is disposed on the plastic front frame.

14. The liquid crystal display as claimed in claim 12, wherein the electromagnetic shield member is fitted or inlaid fixedly to the plastic front frame.

15. The liquid crystal display as claimed in claim. 12, wherein the electromagnetic shield member is one-piece shaped in the interior of the plastic front frame.
